(19) United States
(12) Patent Application Publication
(10) Pub. No.: US 2009/0090928 A1
(43) Pub. Date: Apr. 9, 2009

(54) LIGHT EMITTING MODULE AND METHOD FOR MANUFACTURING THE SAME

(75) Inventors: Haruhiko MORI, Gunma (JP); Takaya Kusabe, Gunma (JP); Tatsuya Motoike, Tottori (JP)

Correspondence Address: MORRISON & FOERSTER LLP, 1650 TYSONS BOULEVARD, SUITE 400, MCLEAN, VA, 22102, US

(73) Assignees: SANYO Electric Co., Ltd., Moriguchi-Shi (JP); SANYO Semiconductor Co., Ltd., Ora-Gun (JP); SANYO Consumer Electronics Co., Ltd., Tottori-Shi (JP)

(21) Appl. No.: 12/238,235

(22) Filed: Sep. 25, 2008

(30) Foreign Application Priority Data
Sep. 25, 2007 (JP) 2007-247875

(51) Int. Cl. H01L 33/00

(52) U.S. Cl. 257/99; 257/100; 438/42; 257/E33.06; 257/E33.066

(57) ABSTRACT

Provided are: a light emitting module capable of ensuring a high heat-dissipating property and mountable in any of sets in various shapes; and a method for manufacturing the light emitting module. The light emitting module mainly includes: a metal substrate; an insulating layer covering the upper surface of the metal substrate; a conductive pattern formed on the upper surface of the insulating layer; and a light emitting element fixedly attached to the upper surface of the metal substrate and electrically connected to the conductive pattern. Furthermore, a groove is formed in the metal substrate, and then the metal substrate is bent. Thus, a bent portion is formed in the metal substrate.

This application claims priority from Japanese Patent Application Number JP 2007-247875 filed on Sep. 25, 2007, the content of which is incorporated herein by reference in its entirety.

### BACKGROUND OF THE INVENTION

1. Field of the Invention

The present invention relates to a light emitting module and a method for manufacturing the same. Particularly, the present invention relates to a light emitting module on which a high-luminance light emitting element is mounted, and a method for manufacturing the light emitting module.

2. Description of the Related Art

A semiconductor light emitting element represented by a light emitting diode (LED) has a long life and shows a high visibility. Accordingly, its use in traffic signals, lamps of automobiles, and the like, has been started. Moreover, use of an LED in lighting equipment is emerging.

When used in lighting equipment, a large number of LEDs are mounted in single lighting equipment, because merely a single LED cannot produce sufficient brightness. However, an LED dissipates a large amount of heat during the light emission. Accordingly, when an LED is mounted on a mounting board made of a resin material that has an inferior heat-dissipating property, or when such LEDs are resin-packaged individually, heat is not desirably dissipated from the LED to the outside. Consequently, the performance of the LED is deteriorated soon.

With reference to Japanese Patent Application Publication No. 2007-194155 (Patent Document 1), disclosed is a technology related to a light source unit in which a metal base circuit board with a packaged LED mounted is bent. Specifically, with reference to FIG. 1 of this document, a packaged LED 6 is mounted on a metal foil 1 that has an insulated surface, and the metal foil 1 is bent at predetermined positions. In this manner, the metal foil 1 is adhered to a case 8 having a heat-dissipating property, so that heat is desirably dissipated from the LED 6 to the outside via the metal foil 1 and the case 8.

Japanese Patent Application Publication No. 2006-100753 (Patent Document 2) discloses a technology in which an LED is mounted on the upper surface of a metal substrate made of aluminum in order to desirably dissipate a heat generated from an LED to the outside. Particularly, with reference to FIG. 2 of Patent Document 2, an upper surface of a metal substrate 11 is covered with an insulating resin 13, a conductive pattern 14 is formed on the upper surface of this insulating resin 13, and then a light emitting element 15 (LED) is mounted on the upper surface of the conductive pattern 14. With this configuration, the heat generated from the light emitting element 15 is dissipated outside via the conductive pattern 14, the insulating resin 13 and the metal substrate 11.

Nevertheless, the technology described in Patent Document 1 aims to incorporate only one packaged LED in the light source unit, and thus is not made on the assumption that multiple LEDs are mounted in a light source unit. Accordingly, the light source unit described in this document produces an insufficient amount of light for use for illumination or the like. Moreover, if multiple LEDs are mounted, the light source unit can produce a larger amount of light as a whole. However, as the number of LEDs mounted is increased, the amount of heat dissipated is also increased accordingly. Thus, unless the heat from the LEDs is desirably dissipated, the temperature of the entire unit may increase so high that the heat will decrease the conversion efficiency of LEDs, or destroy the LEDs.

Furthermore, in the technology described in Patent Document 2, the insulating resin 13 is placed between the metal substrate 11 and the conductive pattern 14 to which the light emitting element 15 of being an LED is fixedly attached. Here, the insulating resin 13 is extensively filled with fillers to improve the heat-dissipating property, but has a high thermal resistance in comparison with a metal. For this reason, when an LED having a high luminance, which a large amount of currents such as 200 mA or larger flows through, is adopted as the light emitting element 15, the heat may not be dissipated sufficiently in the structure described in Patent Document 2.

Still furthermore, in the technology described in Patent Document 2, the metal substrate 11 is a flat plate. Accordingly, it has been difficult to incorporate the metal substrate 11 having an LED mounted thereon, for example, inside a set having a complicated shape (such as a corner of an automobile or the interior of a toy).

### SUMMARY OF THE INVENTION

The present invention has been made in view of the above-described problems. A main object of the present invention is to provide: a light emitting module capable of ensuring a high heat-dissipating property and mountable in any of sets in various shapes; and a method for manufacturing the light emitting module.

A light emitting module according to the present invention includes: a metal substrate whose first main surface is covered with an insulating layer; a conductive pattern formed on a main surface of the insulating layer; and a light emitting element electrically connected to the conductive pattern. A groove is formed in the metal substrate in a second main surface of the metal substrate, and at a position where the groove is formed, the metal substrate is bent to a side opposite to a side where the light emitting element is mounted.

A method for manufacturing a light emitting module according to the present invention includes the steps of: forming a conductive pattern on a main surface of an insulating layer covering a first main surface of a metal substrate; forming a groove in a second main surface of the metal substrate; fixedly attaching a light emitting element on the first main surface of the metal substrate, and electrically connecting the light emitting element to the conductive pattern; and at a position where the groove is formed, bending the metal substrate to a side opposite to a side where the light emitting element is mounted.

Furthermore, another method for manufacturing a light emitting module according to the present invention includes the steps of: forming a conductive pattern constituting a plurality of units, on a surface of an insulating layer covering a first main surface of a substrate; forming separation grooves respectively in the first main surface and the second main surface of the substrate at a position corresponding to a boundary between the units, and forming a bending groove in the substrate corresponding to a position where the units are bent; fixedly attaching a light emitting element on the substrate for each of the units, and electrically connecting the light emitting element to the conductive pattern; at the positions where the separation grooves are formed, separating the substrate into each unit; and at the position where the bending groove is formed, bending the substrate of the unit to a side opposite to a side where the light emitting element is mounted.

### BRIEF DESCRIPTION OF THE DRAWINGS

FIG. 1A is a cross-sectional view and FIG. 1B is a plan view for showing a configuration of a light emitting module according to a preferred embodiment of the present invention.

FIGS. 2A and 2B are cross-sectional views for showing a configuration of the light emitting module according to the preferred embodiment of the present invention.

FIGS. 3A and 3B are cross-sectional views for showing a configuration of the light emitting module according to the preferred embodiment of the present invention.

FIGS. 4A and 4B are cross-sectional views, and FIG. 4C is a plan view, for illustrating a method for manufacturing a light emitting module according to a preferred embodiment of the present invention.

FIGS. 5A to 5C are cross-sectional views, and FIG. 5D is a plan view, for illustrating the method for manufacturing a light emitting module according to the preferred embodiment of the present invention.

FIG. 6A is a cross-sectional view, and FIG. 6B is a plan view, for illustrating the method for manufacturing a light emitting module according to the preferred embodiment of the present invention.

FIG. 7A is a perspective view, FIG. 7B is a cross-sectional view, and FIG. 7C is a plan view, for illustrating the method for manufacturing a light emitting module according to the preferred embodiment of the present invention.

FIGS. 8A to 8C are cross-sectional views for illustrating the method for manufacturing a light emitting module according to the preferred embodiment of the present invention.

FIGS. 9A and 9B are cross-sectional views for illustrating the method for manufacturing a light emitting module according to the preferred embodiment of the present invention.

FIGS. 10A and 10B are cross-sectional views, and FIG. 10C is a plan view, for illustrating the method for manufacturing a light emitting module according to the preferred embodiment of the present invention.

FIGS. 11A and 11B are cross-sectional views, and FIG. 11C is a plan view, for illustrating the method for manufacturing a light emitting module according to the preferred embodiment of the present invention.

FIG. 12A is a cross-sectional view, and FIG. 12B is a plan view, for illustrating the method for manufacturing a light emitting module according to the preferred embodiment of the present invention.

FIGS. 13A and 13B are cross-sectional views for illustrating the method for manufacturing a light emitting module according to the preferred embodiment of the present invention.

FIGS. 14A is a photograph for showing a state of a metal substrate in an experiment, and FIGS. 14B to 14E are SEM images for showing results of experiments where a metal substrate is bent in the method for manufacturing a light emitting module according to the preferred embodiment of the present invention.

### DESCRIPTION OF THE INVENTIONS

### First Embodiment

### Configuration of Light Emitting Module

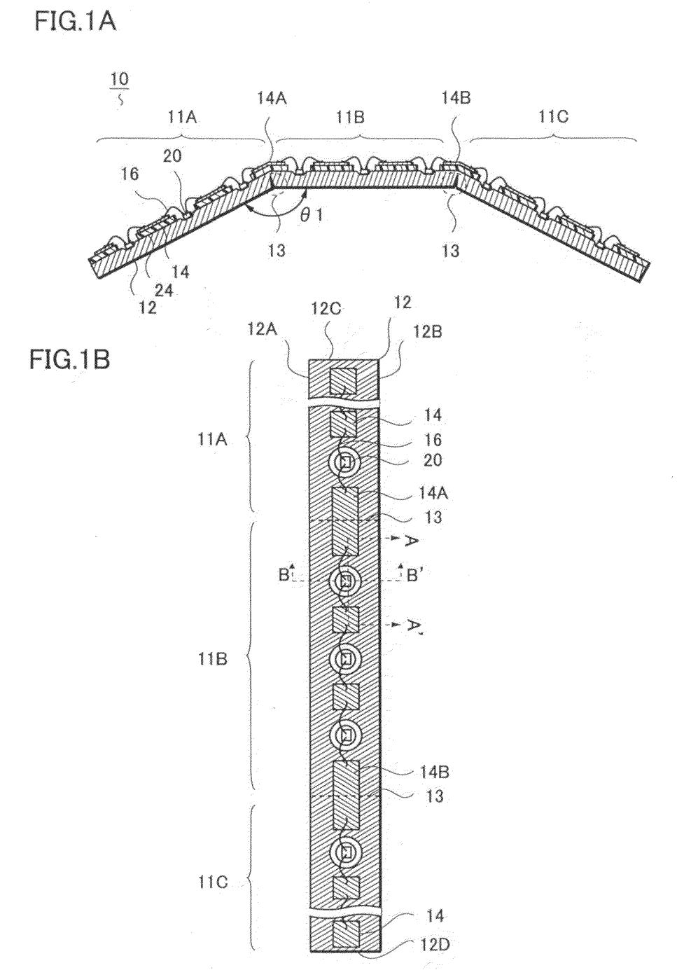

In this embodiment, a configuration of a light emitting module 10 will be described with reference to FIG. 1A to FIG. 3B.

FIG. 1A is a cross-sectional view of the light emitting module 10. FIG. 1B is a plan view of the light emitting module 10 seen from top.

As shown in FIG. 1A, the light emitting module 10 mainly includes: a metal substrate 12; an insulating layer 24 covering the upper surface of the metal substrate 12; a conductive pattern 14 formed on the upper surface of the insulating layer 24; and a light emitting element 20 fixedly attached to the upper surface of the metal substrate 12 and electrically connected to the conductive pattern 14.

The light emitting module 10 has the multiple light emitting elements 20 mounted on the upper surface of the single plate-like metal substrate 12. These light emitting elements 20 are connected to each other in series via the conductive patterns 14 and thin metal wires 16. By supplying a direct current to the light emitting module 10 having such a configuration, a predetermined color of light is emitted from the light emitting element 20. Thus, the light emitting module 10 functions as lighting equipment like a fluorescent lamp, for example.

The metal substrate 12 is a substrate made of a metal such as copper (Cu) or aluminium (Al). The metal substrate 12 has a thickness of approximately 0.5 mm to 2.0 mm, a width of approximately 5 mm to 20 mm, and a length of approximately 10 cm to 50 cm, for example. In order to secure a predetermined amount of light to be produced, a number of light emitting elements 20 are disposed in a line so that the metal substrate 12 can have a considerably thin and narrow form. At each of the two ends in a longitudinal direction of the metal substrate 12, an external connection terminal to be connected to a power source on the outside is formed. This terminal may be an insertion-type connector, or may be formed by soldering a wire to the conductive pattern 14.

The upper surface of the metal substrate 12 is covered with the insulating layer 24 made of a material that has a resin as the main component. On the upper surface of the insulating layer 24, the conductive pattern 14 with a predetermined shape is formed. The light emitting element 20 fixedly attached to the upper surface of the metal substrate 12 is connected to the conductive pattern 14 via the thin metal wire 16.

The conductive pattern 14 is formed on the upper surface of the insulating layer 24, and functions as part of a pathway for conducting electricity to each light emitting element 20. The conductive pattern 14 is formed by etching a conductive foil made of copper or the like that is disposed on the upper surface of the insulating layer 24. Furthermore, the conductive patterns 14 provided at the two end of the metal substrate 12 may function, in some cases, as external connection terminals contributing to the connection to the outside.

In the light emitting module 10 of this embodiment, a bent portion 13 is formed by bending the metal substrate 12 in a thickness direction. Here, with the two bent portions 13 acting as boundaries, the light emitting module 10 is divided into module segments 11A, 11B, 11C. In each module segment, the predetermined number of light emitting elements 20 are disposed and connected to each other, and the metal substrate 12 in each module segment is formed flat.

The bent portion 13 is formed by cutting a groove in the back surface of the metal substrate 12 and then by bending the metal substrate 12 along the groove. Here, a groove with a V-shaped cross section is formed in the back surface of the metal substrate 12, and the metal substrate 12 is bent in such a way as to close this groove. To put in another way, a direction in which the metal substrate 12 is bent at the bent portion 13 is opposite to a direction in which the light emitting elements 20 are mounted on the metal substrate 12. In FIG. 1A, the light emitting elements 20 are fixedly attached to the upper surface of the metal substrate 12, and the metal substrate 12 is bent downwards at the bent portions 13.

The module segments partitioned by the bent portions 13 are electrically connected to each other with the conductive patterns that extend over the bent portions 13. Specifically, a conductive pattern 14A extends, from its center, over the module segment 11A on the left side of FIG. 1A and the module segment 11B. This conductive pattern 14A extends over the bent portion 13 from the module segment 11A to the module segment 11B. More specifically, the light emitting element 20 positioned on the rightmost end of the module segment 11A is electrically connected to the light emitting element 20 positioned on the leftmost end of the module segment 11B via the thin metal wires 16 and the conductive pattern 14A.

Similarly, the module segment 11B in the center and the module segment 11C on the right side are connected to each other with a conductive pattern 14B that extends over the bent portion 13 positioned between the module segments 11B and 11C.

By providing the conductive patterns 14A, 14B over the bent portions 13 as described above, all of the light emitting elements 20 included in each of the module segments 11A, 11B, 11C partitioned by the bent portions 13 can be electrically connected to each other.

In this respect, it is possible to use connecting means such as a thin metal wire in place of the conductive patterns 14A, 14B. In this case, the conductive pattern 14 on the rightmost end of the module segment 11A is connected to the conductive pattern 14 on the leftmost end of the module segment 11B via the thin metal wire.

As shown in FIG. 1B, the metal substrate 12 has a first side surface 12A and a second side surface 12B which are side surfaces in the longitudinal direction as well as a third side surface 12C and a fourth side surface 12D which are side surfaces in the latitudinal direction. As described above, the metal substrate 12 of this embodiment has a thin and narrow form with a width of approximately 2 mm to 50 mm, a length of approximately 5 cm to 50 cm, for example. On the metal substrate 12, the light emitting elements 20 and the conductive patterns 14 are arranged in a line in the longitudinal direction.

In FIG. 1B, the bent portions 13 are indicated by dotted lines. In the bent portions 13, the grooves provided in the back surface of the metal substrate 12 are continuously formed from the first side surface 12A to the second side surface 12B. This configuration provides an advantage that a bending process at the bent portions 13 of the metal substrate 12 is facilitated.

In the above description, the two bent portions 13 are formed in the metal substrate 12; nonetheless, a larger number of bent portions 13 can be formed in the metal substrate 12. Furthermore, as shown in FIG. 1A, the bent portion 13 has an angle θ1 that is an obtuse angle (for example, 150 degrees), however, this angle θ1 may be a right angle or an acute angle.

Referring back to FIG. 1A, grooves may be formed in the upper surface of the bent portions 13 of the metal substrate 12 then to perform a bending process thereon so that the metal substrate 12 as a whole can have its convex portion directed downwards in FIG. 1A. Furthermore, it is possible to form grooves in the upper surface and the lower surface of the bent portions 13 of the metal substrate 12 and thus to perform a bending process on these portions.

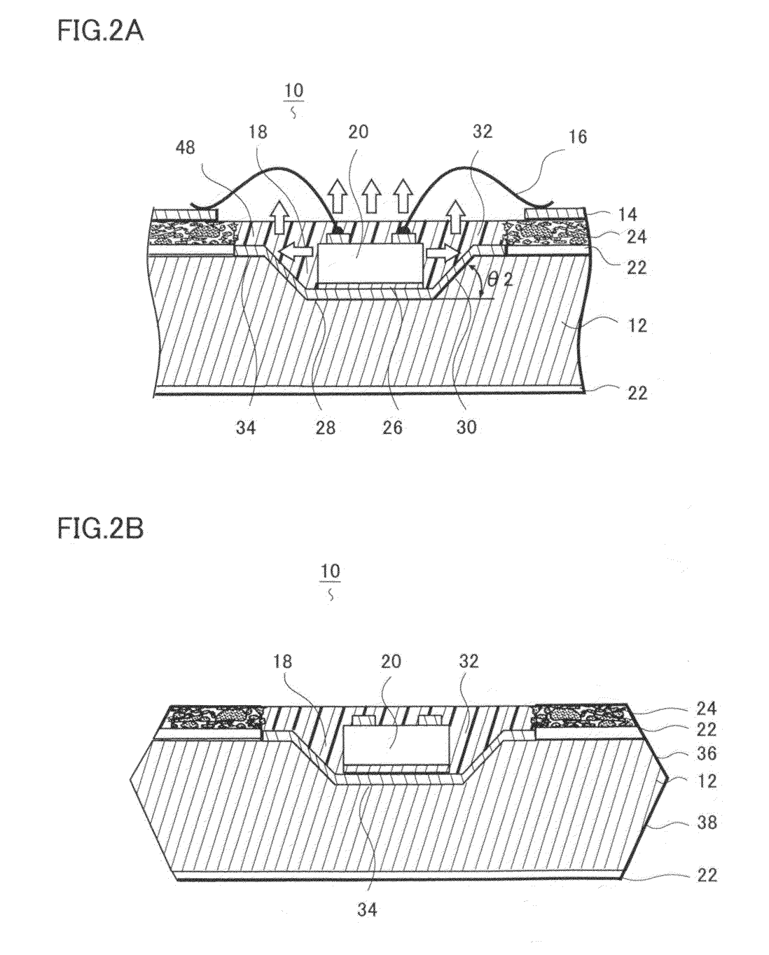

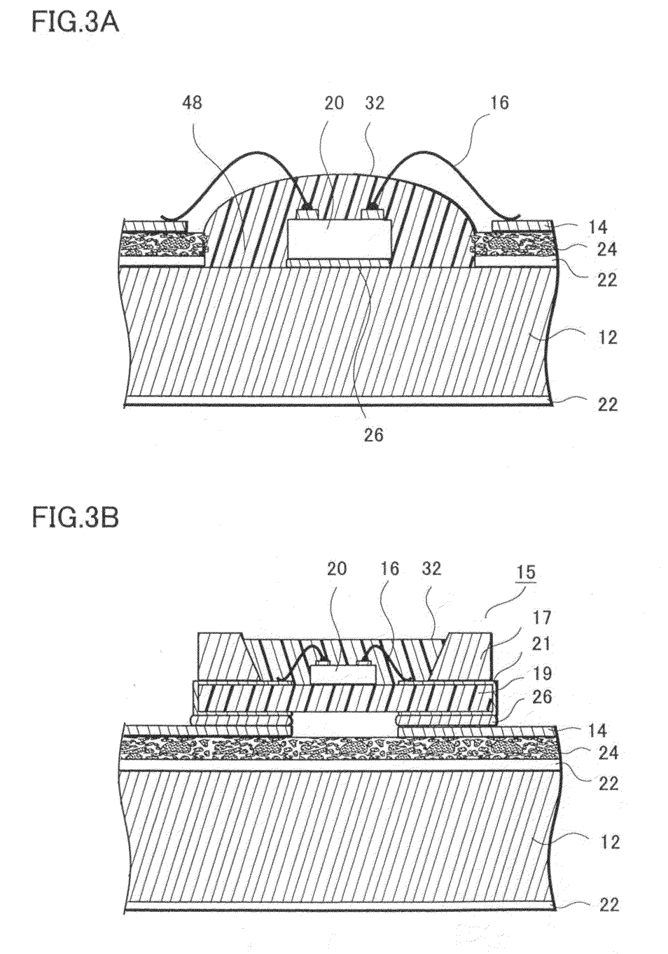

Next, specific configurations of the light emitting elements 20 and the like mounted on the metal substrate 12 will be described with reference to FIG. 2 and FIG. 3.

FIG. 2A is a cross-sectional view taken along the line A-A′ shown in FIG. 1B. FIG. 2B is a cross-sectional view taken along the line B-B′ shown in FIG. 1B.

As shown in FIG. 2A and FIG. 2B, in this embodiment, the insulating layer 24 is partially removed to form an opening portion 48, and the light emitting element 20 is mounted on a portion exposed from the opening portion 48 on the upper surface of the metal substrate 12. Additionally, in this embodiment, a concave portion 18 is formed by partially denting the upper surface of the metal substrate 12 to have a concave, and the light emitting element 20 is accommodated in the concave portion 18.

Hereinafter, detailed description will be given of the light emitting module 10 having such a configuration.

Firstly, when the metal substrate 12 is made of aluminium, the upper surface and the lower surface of the metal substrate 12 are covered with an oxide film 22 (alumite film: Al₂(SO₄)₃) obtained by anodizing aluminium. As shown in FIG. 2A, the thickness of the oxide film 22 covering the metal substrate 12 is, for example, approximately 1 μm to 10 μm.

As shown in FIG. 2B, the side surfaces of the metal substrate 12 are formed so as to protrude outwards. Specifically, each of the side surfaces of the metal substrate 12 is formed by: a first inclined portion 36 that continuously inclines from the upper surface of the metal substrate 12 to the outside; and a second inclined portion 38 that continuously inclines from the lower surface of the metal substrate 12 to the outside. This configuration makes it possible to have large areas of the side surfaces of the metal substrate 12 in comparison with a configuration where a metal substrate 12 has flat side surfaces and thus to increase the amount of heat dissipated from the side surfaces of the metal substrate 12 to the outside. Particularly, the side surfaces of the metal substrate 12 are not covered with the oxide film 22 having a high thermal resistance, and the metal material superior in a heat-dissipating property is exposed from these side surfaces. Thus, with this configuration, the heat-dissipating property of the entire module is improved.

As shown in FIG. 2A, the upper surface of the metal substrate 12 is covered with the insulating layer 24 made of a resin (thermoplastic resin or thermosetting resin) in which fillers such as Al₂O₃ are mixed. The thickness of the insulating layer 24 is, for example, approximately 50 μm. The insulating layer 24 has a function to insulate the metal substrate 12 and the conductive pattern 14 from each other. Moreover, the insulating layer 24 has a large amount of fillers mixed therein. This enables the thermal expansion coefficient of the insulating layer 24 to be closer to that of the metal substrate 12, and also reduces the thermal resistance of the insulating layer 24. For example, the insulating layer 24 contains the approximately 70 to 80 volume % of fillers. Furthermore, the average particle diameter of the fillers contained therein is, for example, approximately 4 μm or approximately 10 μm.

Here, in this embodiment, the light emitting element 20 is not mounted on the upper surface of the insulating layer 24. This can decrease the amount of fillers that are contained in the insulating layer 24. Alternatively, the insulating layer 24 may be made of only a resin that does not contain fillers. Specifically, the amount of fillers contained in the insulating layer 24 can be, for example, 50% by volume or less. In this manner, the flexibility of the insulating layer 24 can be improved. Thus, even when the bending process is performed on the metal substrate 12 to form the bent portions 13 as shown in FIG. 1A, the bending stress generated due to the bending process is mitigated by the insulating layer 24. This prevents damage to the insulating layer 24 and the conductive pattern 14 due to the bending process.

The light emitting element 20 includes two electrodes (anode, cathode) on the upper surface thereof, and emits light of a predetermined color. The light emitting element 20 has a structure in which an N type semiconductor layer and a P type semiconductor layer are stacked on the upper surface of a semiconductor substrate made of GaAs, GaN, or the like. The specific size of the light emitting element 20 is: for example, approximately 0.3 mm to 1.0 mm in length, 0.3 mm to 1.0 mm in width, and 0.1 mm in thickness. Moreover, the thickness of the light emitting element 20 varies depending on the color of light to be emitted. For example, the thickness of the light emitting element 20 that emits a red light is approximately 100 μm to 3000 μm. The thickness of the light emitting element 20 that emits a green light is approximately 100 μm. The thickness of the light emitting element 20 that emits a blue light is approximately 100 μm. When a voltage is applied to the light emitting element 20, light is emitted from the upper surface and top portions of side surfaces. The configuration of the light emitting module 10 according to the preferred embodiment of the present invention has a superior heat-dissipating property and, therefore is particularly effective on the light emitting element 20 (power LED) through which a current of 100 mA or larger passes, for example.

In FIG. 2A, light emitted from the light emitting element 20 is indicated by white arrows. The light emitted from the upper surface of the light emitting element 20 is irradiated upward without interference. Meanwhile, the light emitted sideways from the side surfaces of the light emitting element 20 reflects upward on side surface 30 of the concave portion 18. Furthermore, the light emitting element 20 is covered with a sealing resin 32 in which a fluorescent material is mixed; accordingly, the light emitted from the light emitting element 20 transmits through the sealing resin 32 and is emitted to the outside.

The two electrodes (anode, cathode) are disposed on the upper surface of the light emitting element 20. These electrodes are connected to the conductive patterns 14 via the thin metal wires 16. Here, each connecting portion between the electrode of the light emitting element 20 and the thin metal wire 16 is covered with the sealing resin 32.

With reference to FIG. 2A, description will be given of a shape of the portion where the light emitting element 20 that is an LED is mounted. Firstly, an opening portion 48 is formed by removing part of the insulating layer 24 to have a circular portion. Then, by denting a portion in the upper surface of the metal substrate 12, the portion being exposed from the inner side of the opening portion 48, the concave portion 18 is thus formed. The light emitting element 20 is fixedly attached to a bottom surface 28 of the concave portion 18. Moreover, the light emitting element 20 is covered with the sealing resin 32 filled in the concave portion 18 and the opening portion 48.

The concave portion 18 is formed in the metal substrate 12 by denting the upper surface, and the bottom surface 28 has a circular shape. Moreover, the side surface 30 of the concave portion 18 functions as a reflector for reflecting light upward, the light having been emitted from the side surface of the light emitting element 20 towards the sides. The outer side of the side surface 30 and the bottom surface 28 form an angle θ2 of approximately 40 degrees to 60 degrees, for example. The depth of the concave portion 18 may be greater or smaller than the thickness of the light emitting element 20. For example, when the thickness of the concave portion 18 is set to be greater than a length equivalent to the thickness obtained by adding the thickness of the light emitting element 20 and that of a bonding material 26, the light emitting element 20 can be accommodated in the concave portion 18 and the upper surface of the light emitting element 20 can be positioned lower than the upper surface of the metal substrate 12. This contributes to the formation of a thin module as a whole.

The bottom surface 28 and the side surface 30 of the concave portion 18 as well as the upper surface of the metal substrate 12 near the concave portion 18 are covered with a cover layer 34. As a material of the cover layer 34, used is gold (Au) or silver (Ag) formed by a plating process. In addition, when a material (for example, gold or silver) that has a higher reflectance than the material of the metal substrate 12 is used as the material of the cover layer 34, the light emitted from the light emitting element 20 sideways can be reflected upward more efficiently. Moreover, the cover layer 34 has a function to prevent the inner wall of the concave portion 18, on which the metal is exposed, from being oxidized in a manufacturing process of the light emitting module 10.

Furthermore, on the bottom surface 28 of the concave portion 18, the oxide film 22 that covers the surface of the metal substrate 12 is removed. The oxide film 22 has a higher thermal resistance than the metal that constitutes the metal substrate 12. Thus, by removing the oxide film 22 from the bottom surface 28 of the concave portion 18 on which the light emitting element 20 is mounted, the thermal resistance of the entire metal substrate 12 is reduced.

The sealing resin 32 is filled in the concave portion 18 and the opening portion 48 to seal the light emitting element 20. The sealing resin 32 is formed by mixing a fluorescent material into a silicone resin superior in thermal resistance. For example, when a blue light is emitted from the light emitting element 20 and a yellow fluorescent material is mixed into the sealing resin 32, the light transmitted through the sealing resin 32 turns white. Accordingly, it is possible to utilize the light emitting module 10 as lighting equipment that emits a white light. Moreover, the side surface of the insulating layer 24, facing the opening portion 48, is a coarse surface from which the fillers are exposed. The coarse side surface of the insulating layer 24 exhibits an anchoring effect between the side surface and the sealing resin 32, and brings about an advantage to prevent separation of the sealing resin 32.

Still furthermore, referring to FIG. 2A, the sealing resin 32 may be formed in such a way as to cover the thin metal wires 16 entirely. In this case, a connecting portion between the thin metal wire 16 and the light emitting element 20 as well as a connecting portion between the thin metal wire 16 and the conductive pattern 14 are both covered with the sealing resin 32.

The bonding material 26 has a function to bond a lower surface of the light emitting element 20 and the concave portion 18. Since the light emitting element 20 does not have an electrode on the lower surface, the bonding material 26 may be formed of a resin with an insulating property or may be formed of a metal such as solder to improve the heat-dissipating property. Meanwhile, since the bottom surface 28 of the concave portion 18 is covered with a plating film (cover layer 34) made of silver or the like superior in solder wettability, it is possible to employ solder as the bonding material 26 readily.

The preferred embodiment of the present invention is advantageous in that mounting the bare light emitting element 20 on the upper surface of the metal substrate 12 causes the heat generated from the light emitting element 20 to be dissipated to the outside in a significantly efficient manner. To be more specific, in the above-described conventional example, the light emitting element is mounted on the conductive pattern formed on the upper surface of the insulating layer, and accordingly the insulating layer inhibits the thermal conductivity. This makes it difficult to dissipate the heat from the light emitting element 20 to the outside efficiently. On the other hand, in the preferred embodiment of the present invention, the opening portion 48 is formed by removing the insulating layer 24 and the oxide film 22 in the region where the light emitting element 20 is to be mounted. The light emitting element 20 is fixedly attached to the surface of the metal substrate 12, the surface being exposed from this opening portion 48. Thereby, heat generated from the light emitting element 20 is immediately conducted to the metal substrate 12, and dissipated to the outside. Thus, the rising of the temperature of the light emitting element 20 is suppressed. Moreover, by the suppression of the temperature rising, the deterioration of the sealing resin 32 is suppressed.

Furthermore, according to the preferred embodiment of the present invention, the side surface 30 of the concave portion 18 provided in the upper surface of the metal substrate 12 can be utilized as the reflector. Specifically, as shown in FIG. 2A, the side surface 30 of the concave portion 18 is an inclined surface such that the width of the concave portion is gradually increased toward the upper surface of the metal substrate 12. This side surface 30 reflects light emitted sideways from the side surface of the light emitting element 20 to guide the irradiation of the light upward. In other words, the side surface 30 of the concave portion 18 accommodating the light emitting element 20 also functions as the reflector. This eliminates the need to independently prepare a reflector as in a generally-used light emitting module, thereby reducing the number of components as well as the production cost. Additionally, by covering the side surface 30 of the concave portion 18 with the material having a higher reflectance as described above, the function of the side surface 30 as the reflector can be enhanced.

Another configuration where a light emitting element 20 is mounted on a metal substrate 12 will be described with reference to FIG. 3A. In this configuration shown in the drawing, a concave portion 18 as described above is not formed. The light emitting element 20 is directly mounted on the upper surface of the metal substrate 12, which is exposed from an opening portion 48, with a bonding material 26. A sealing resin 32 is formed to fill the opening portion 48 and to cover the side surfaces and upper surface of the light emitting element 20.

As has just been described, in this embodiment, the light emitting element 20 is directly fixedly attached to the upper surface of the metal substrate 12. This decreases the amount of filler contained in an insulating layer 24, and makes the insulating layer 24 superior in flexibility. Thus, even when the metal substrate 12 is bent at the bent portion 13 shown in FIG. 1A, it is possible to prevent damage to the insulating layer 24 and a conductive pattern 14 due to the bending.

Next, a structure where a packaged light emitting element 20 as a semiconductor device 15 is mounted on a metal substrate 12 will be described with reference to FIG. 3B.

The semiconductor device 15 includes: a mounting board 19; the light emitting element 20 mounted on the upper surface of the mounting board 19; a reflection frame 17 fixedly attached to the upper surface of the mounting board 19 in such a way as to surround the light emitting element 20; a sealing resin 32 sealing the light emitting element 20; and a conductive path 21 electrically connected to the light emitting element 20.

The mounting board 19 is made of a resin material such as a glass epoxy resin or an inorganic material such as a ceramic, and has a function to mechanically support the light emitting element 20. On the upper surface of the mounting board 19, the light emitting element 20 and the reflection frame 17 are disposed. Specifically, the light emitting element 20 is disposed neighboring the central portion of the upper surface of the mounting board 19. The reflection frame 17 is fixedly attached to the upper surface of the mounting board 19 in such a way as to surround the light emitting element 20.

The reflection frame 17 is made of a metal such as aluminium shaped into a frame-like shape. The inner side surface of the reflection frame 17 is inclined in such a way that the lower edge of the inner side surface is located closer to the center of the reflection frame 17 than the upper edge is. Thus, light emitted sideways from the side surface of the light emitting element 20 reflects upward on the inner side surface of the reflection frame 17. In addition, the sealing resin 32 sealing the light emitting element 20 is filled in a region surrounded by the reflection frame 17.

The conductive path 21 is placed along the side surfaces of the mounting board 19 from the upper surface to the lower surface. On the upper surface of the mounting board 19, the conductive path 21 is electrically connected to the light emitting element 20 via a thin metal wire 16. The conductive path 21 formed on the lower surface of the mounting board 19 is connected to a conductive pattern 14 with a bonding material 26, the conductive pattern 14 being formed above the upper surface of the metal substrate 12.

### Second Embodiment

### Method for Manufacturing Light Emitting Module

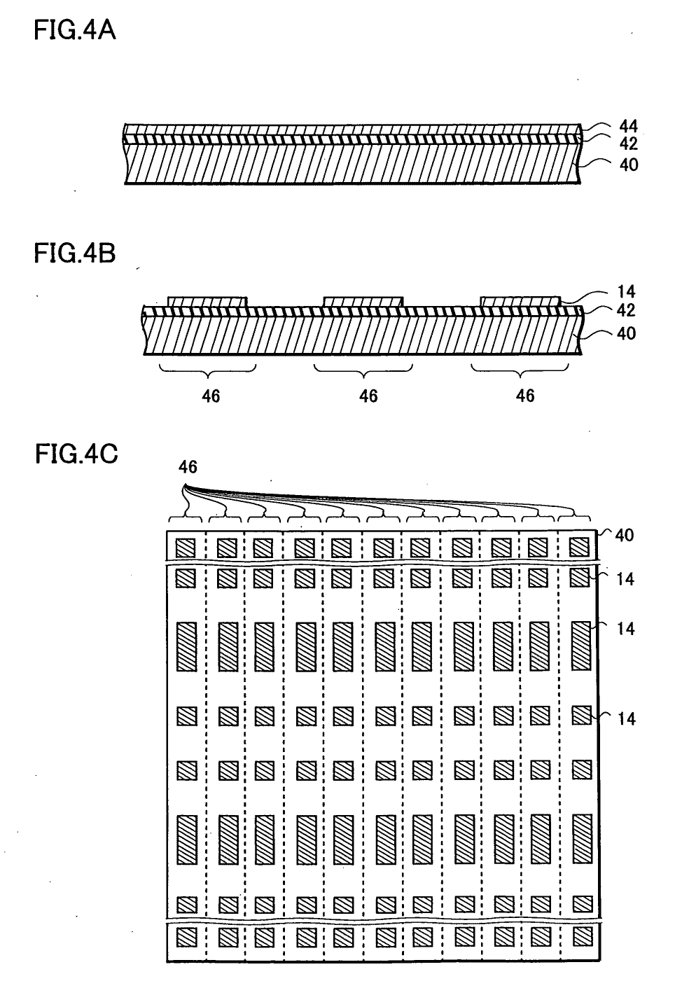

Hereinafter, a method for manufacturing a light emitting module 10 with the above-described configuration will be described with reference to FIG. 4A to FIG. 13B.

First step: see FIGS. 4A to 4C

As shown in FIGS. 4A to 4C, firstly, a substrate 40 that is a base member for the light emitting module 10 is prepared, and a conductive pattern is formed.

Refer to FIG. 4A. At first, the substrate 40 is made of a metal that has, for example, copper or aluminium as the main material, and has a thickness of approximately 0.5 mm to 2.0 mm. The planar size of the substrate 40 is, for example, approximately 1 m×1 m, and the single substrate 40 produces multiple light emitting modules. When the substrate 40 is a substrate made of aluminium, the upper surface and the lower surface of the substrate 40 are covered with the above-described anodized film.

The upper surface of the substrate 40 is entirely covered with an insulating layer 42 having a thickness of approximately 50 μm. The composition of the insulating layer 42 is the same as that of the above-described insulating layer 24. The insulating layer 42 is accordingly made of a resin material (thermoplastic resin or thermosetting resin) that is extensively filled with fillers. Here, in order to prevent damage to a conductive pattern due to bending of the substrate in a later step, the insulating layer 42 may be formed of a resin containing a small amount of fillers (for example, filling ratio of 50% by volume or less), or may be formed of a resin material only. Moreover, on the entire upper surface of the insulating layer 42, a conductive foil 44 made of copper with a thickness of approximately 50 μm is formed.

Then, as shown in FIG. 4B, the conductive foil 44 is patterned by selectively performing wet etching to form conductive patterns 14. Units 46 provided to the substrate 40 each have the same pattern of the conductive patterns 14. Herein, each unit 46 is a portion that constitutes a single light emitting module.

FIG. 4C shows a plan view of the substrate 40 after the completion of this step. Here, each boundary between the adjacent units 46 is indicated by a dotted line. The unit 46 is, for example, approximately 30 cm in length and 0.5 cm in width, and has a considerably thin and narrow form.

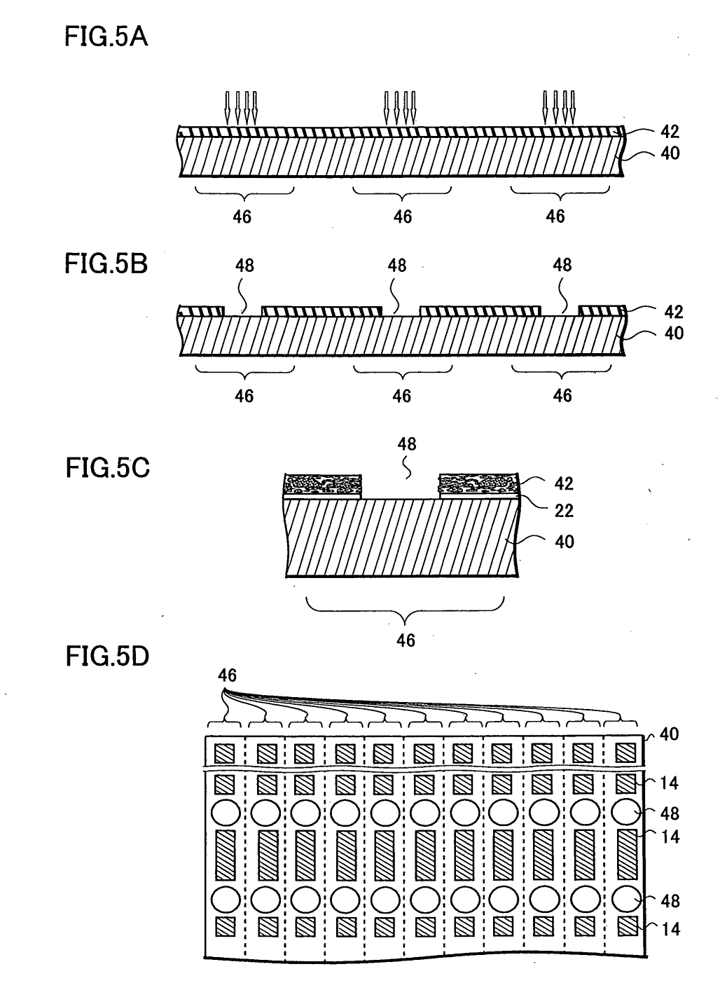

Second step: see FIGS. 5A to 5D

Next, as shown in FIGS. 5A to 5D, the insulating layer 24 is partially removed from the substrate 40 for each unit 46 to form opening portions 48.

As shown in FIG. 5A, the insulating layer 42 is irradiated with a laser from top. Here, the laser used for the irradiation is indicated by an arrow. Portions, corresponding to light emitting elements to be mounted, of the insulating layer 42 are irradiated with the laser. Herein, a YAG laser is preferably used.

As shown in FIG. 5B and FIG. 5C, by the above laser irradiation, part of the insulating layer 42 is removed to have a circular or rectangular shape, and thereby the opening portions 48 are formed. Particularly, as shown in FIG. 5C, the laser irradiation removes not only the insulating layer 42 but also an oxide film 22 that covers the upper surface of the substrate 40. As a result, the metal material (for example, aluminium) constituting the substrate 40 is exposed from the bottom surfaces of the opening portion 48.

As shown in FIG. 5D, each of the above-described opening portions 48 has a circular or rectangular shape. The opening portions 48 are formed so as to correspond to regions where the light emitting elements of each unit 46 are fixedly attached. Here, the planar size of the formed opening portion 48 is larger than that of a concave portion to be formed inside the opening portion 48 in a later step. In other words, the outer-periphery edge portion of the opening portion 48 is away from the outer-periphery edge portion of the concave portion to be formed. Thereby, it is possible to suppress destruction of the fragile insulating layer 42 due to an impact applied thereto during pressing for the concave portion formation.

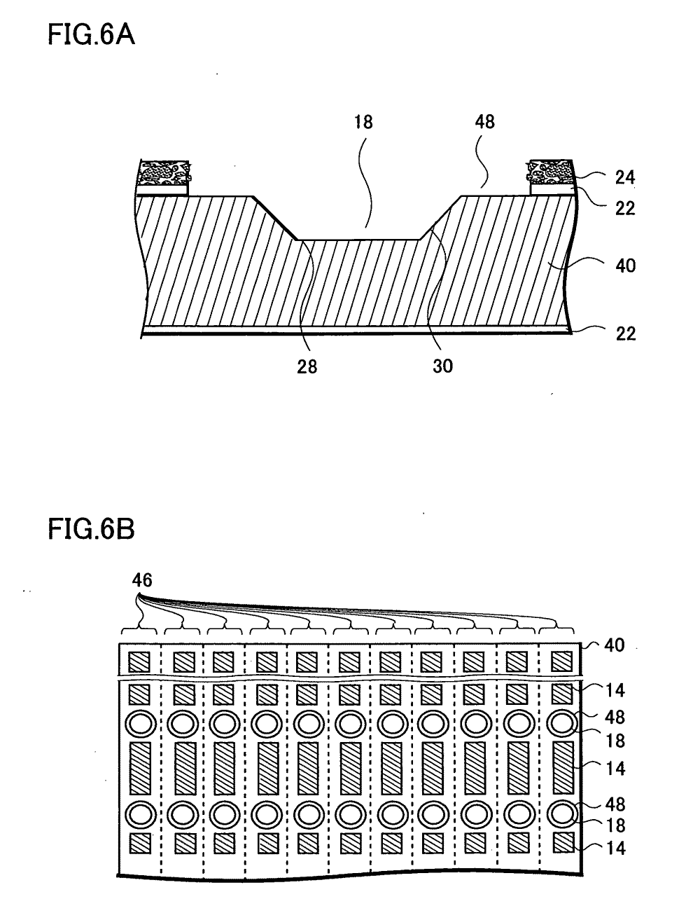

Third step: FIGS. 6A and 6B

Next, as shown in FIGS. 6A and 6B, concave portions 18 are formed in the upper surface of the substrate 40, which is exposed from the opening portions 48. The concave portions 18 may be formed by selective etching, drilling, pressing, or other processes. In this step, the pressing process is adopted.

FIG. 6A shows the shape of the concave portion 18 thus formed. By the pressing process, the concave portion 18 is formed, which has a circular bottom surface 28 and an inclined side surface 30. Moreover, the depth of the concave portion 18 thus formed may be so deep that the light emitting element to be mounted in a later step is completely accommodated therein, or that the light emitting element is partially accommodated therein. Specifically, the depth of the concave portion 18 is, for example, approximately 100 μm to 300 μm.

As shown in FIG. 6B, in the regions of each unit 46 where the light emitting elements are to be mounted, the concave portions 18 are formed by the method described above.

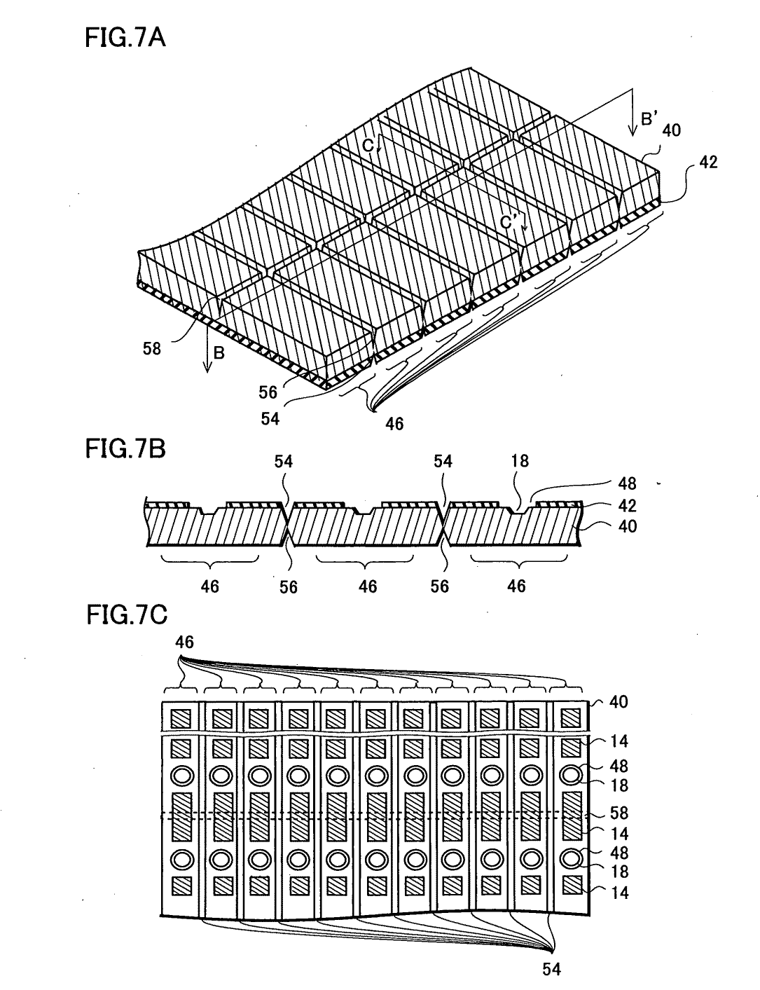

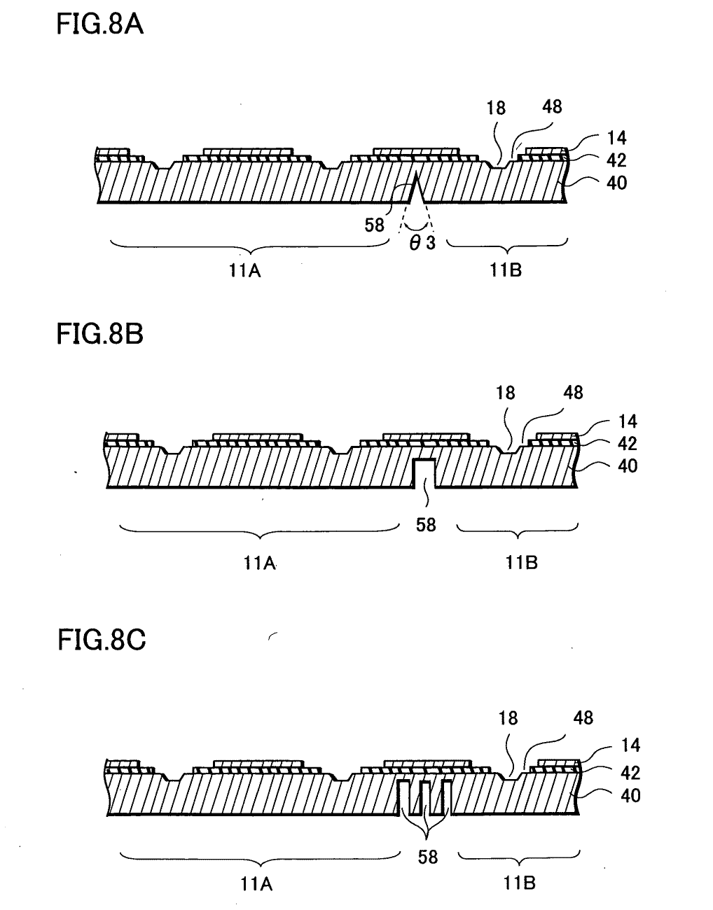

Fourth step: see FIG. 7A to FIG. 8C

In this step, separation grooves (a first groove 54 and a second groove 56) for separation are formed between the two adjacent units 46, and a groove 58 for bending is formed in each unit 46. In this step, these grooves can be formed at once by a cutting saw that rotates at a high speed.

FIG. 7A is a perspective view of the substrate 40 after these grooves are formed. FIG. 7B is a cross-sectional view taken along the line B-B′ in FIG. 7A. FIG. 7C is a plan view of the substrate 40 seen from the bottom in FIG. 7A.

FIG. 7A shows the substrate 40 in a state in which a main surface thereof, where the insulating layer 42 is formed, face downward, for the purpose of illustrating the grooves 58 formed in the substrate 40. Here, the first groove 54, the second groove 56 and the groove 58 are each formed to be parallel to the corresponding side of the substrate 40. The groove 58 is formed in a direction perpendicular to the first groove 54 and the second groove 56.

The groove 58 is formed for bending each unit 46 in a later step. Here, the groove 58 has a V-shaped cross section. The depth of the groove 58 is set to be smaller than the thickness of the substrate 40. For example, when the thickness of the substrate 40 is 1.5 mm, the depth of the groove 58 is approximately 1.0 mm.

As shown in FIG. 7B and FIG. 7C, between the two adjacent units 46, the first groove 54 is formed in the main surface where the insulating layer 42 is formed, and the second grooves 56 are formed in the opposite surface. Each of the cross sections grooves 54 and 56 has a V-shaped shape. The length equivalent to the depth obtained by adding the depth of the first groove 54 and that of the second groove 56 is set to be shorter than the thickness of the substrate 40. Therefore, even after the two grooves are formed, the substrate 40 is still a single plate as a whole. Herein, the size (depth) of the first groove 54 may be the same as that of the second groove 56, or one may be formed to be larger than the other. Furthermore, it is possible to form only either the first groove 54 or the second groove 56.

With reference to FIGS. 8A to 8C, shapes of the cross section of the groove 58 formed in this step will be described. FIGS. 8A to 8C are cross-sectional views respectively showing the shapes of the groove 58 formed for bending the substrate.

In this embodiment, as has been shown in FIG. 1, multiple module segments 11A, 11B, and the like, are formed in a single metal substrate 12 (the above-described unit 46). In the boundary between the module segments, the groove 58 is formed for facilitating a bending process. Thus, various shapes can be employed as the shape of the cross section of the groove 58, as long as the shape facilitates the bending of the metal substrate.

In FIG. 8A, the groove 58 having a V-shaped cross section is formed in the boundary between the module segment 11A and the module segment 11B. Here, an angle θ3 of the V-shaped groove 58 is, for example, approximately 30° to 90°, and is altered in accordance with the angle at which the substrate 40 is bent.

FIG. 8B shows that a groove 58 having a quadrangular-shaped cross section is formed in the boundary between the module segment 11A and the module segment 11B. Even with this groove 58 having such a shape, the thickness of a region where the groove 58 is formed in the substrate 40 is decreased. Thus, the substrate 40 can be bent at this region easily. Here, the bottom surface of the groove 58 may be curved so that the groove 58 has a U-shaped cross section.

FIG. 8C shows that multiple grooves 58 are formed in the boundary between the module segment 11A and the module segment 11B. By forming such multiple grooves 58, the substrate 40 can be bent easily, and the bending of the substrate 40 causes less damage to the insulating layer 42 and the conductive patterns 14. Here, the shape of the cross sections of the multiple grooves 58 may be other than the quadrangular shape. The shape of the cross sections may be, for example, a V shape, U shape, or the like, as described above.

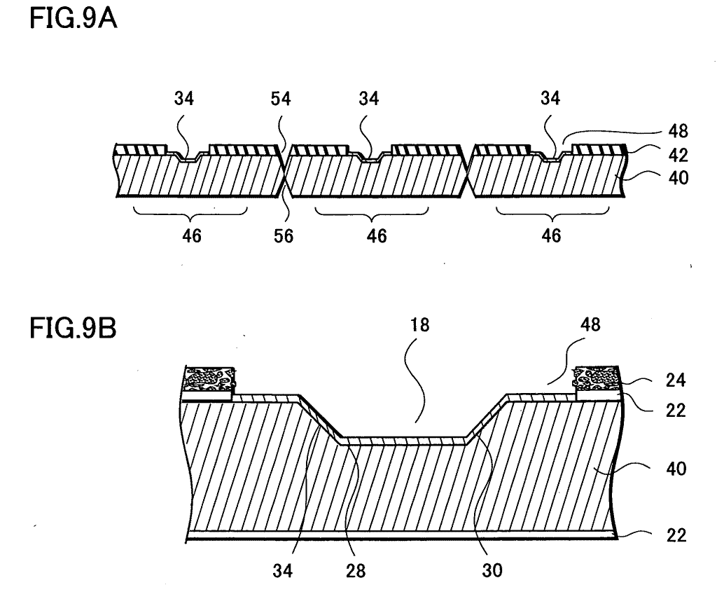

Fifth step: see FIGS. 9A and 9B

In this step, the surfaces of the substrate 40, which are exposed from the opening portions 48, are covered with cover layers 34.

Specifically, the substrate 40 made of a metal is energized as an electrode, and thereby the cover layers 34 of plating films are adhered to the surfaces of the substrate 40 exposed from the opening portion 48. In other words, the cover layers 34 are formed by an electroplating process. As a material of the cover layers 34, gold, sliver, or the like is used. Meanwhile, in order to prevent the plating films from adhering to the surfaces of the first groove 54, the second groove 56 and the groove 58 (see FIGS. 7A to 7C), the surfaces of these portions should be covered with a resist. In addition, since the back surface of the substrate 40 is covered with an oxide film that is an insulator, the plating film does not adhere thereto.

In this step, by covering the concave portion 18 with the cover layer 34, the metal surface of the substrate 40 made of, for example, aluminium is prevented from being oxidized. Furthermore, if the cover layer 34 is a material, such as silver, superior in solder wettability, the light emitting element can be mounted with solder easily on the bottom surface 28 of the concave portion 18 in a step after the step of covering the bottom surface 28 with the cover layer 34. Still furthermore, the function of the side surface 30 of the concave portion 18 as a reflector is improved, by covering the side surface 30 with the cover layer 34 made of a material having a high reflectance.

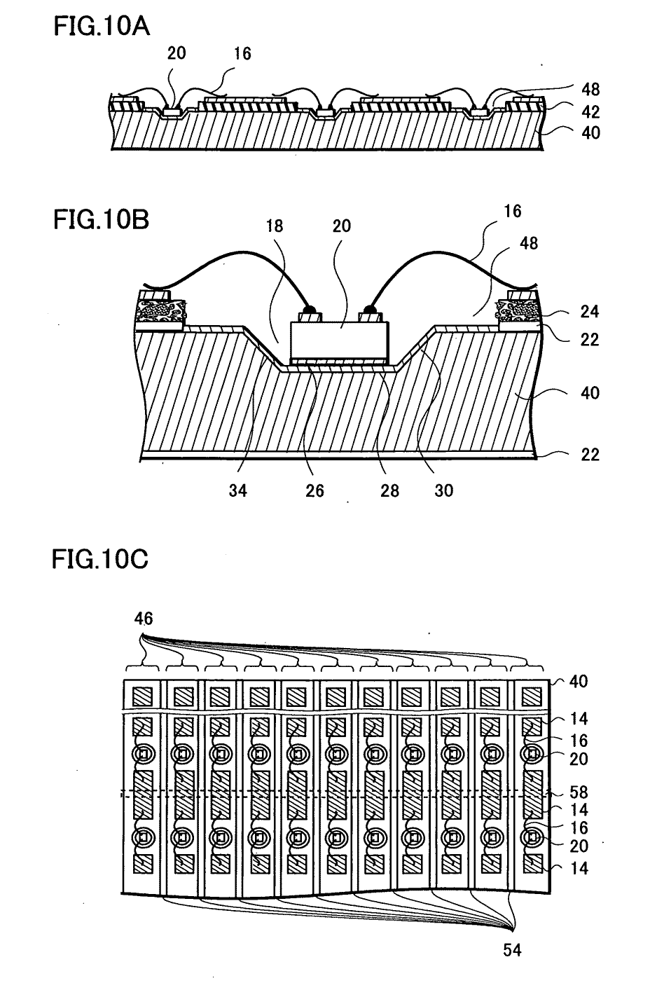

Sixth step: see FIG. 10

Next, light emitting elements 20 (LED chips) are mounted on the concave portions 18 of each unit 46 and electrically connected to conductive patterns.

As shown in FIG. 10A and FIG. 10B, the lower surface of the light emitting element 20 is mounted on the bottom surface 28 of the concave portion 18 with a bonding material 26. Since the light emitting element 20 does not have an electrode on the lower surface thereof, any of conductive adhesive material and an insulating adhesive which are made of resin is used as the bonding material 26. Moreover, as the conductive adhesive material, any of solder and a conductive paste can be employed. Furthermore, the bottom surface 28 of the concave portion 18 is covered with a plating film, such as silver, superior in solder wettability. Thus, solder superior in thermal conductivity to an insulating material can be employed as the bonding material 26.

After the completion of fixedly attaching the light emitting element 20, each electrode provided to the upper surface of the light emitting element 20 is connected to the conductive pattern 14 via a thin metal wire 16.

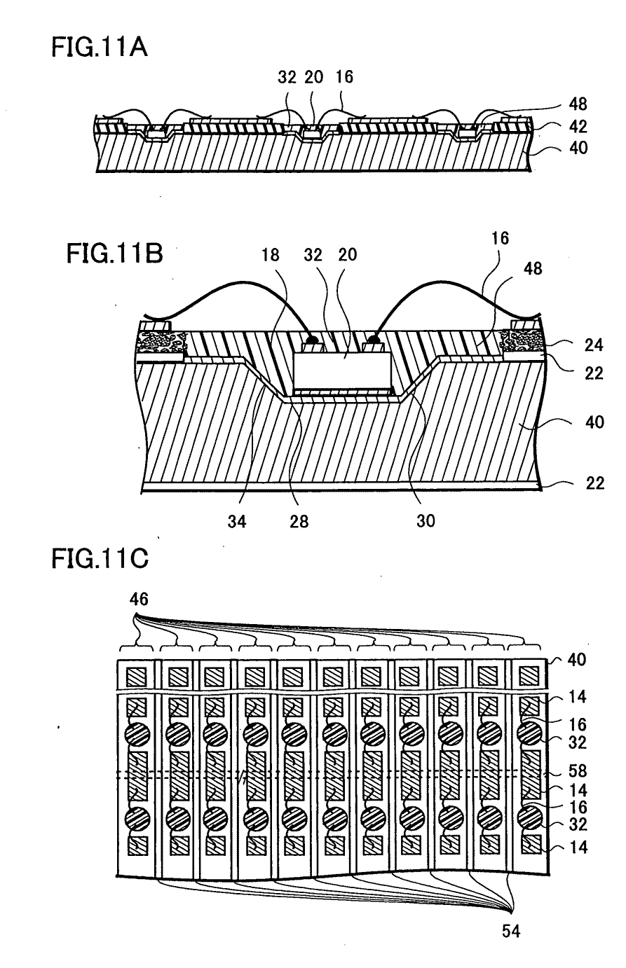

Seventh step: see FIG. 11

Next, the concave portions formed in the substrate 40 for each unit 46 are filled with a sealing resin 32 to seal the light emitting elements 20. The sealing resin 32 is made of a silicone resin in which a fluorescent material is mixed. The sealing resin 32 in a state of liquid or semisolid is filled into the concave portion 18 and the opening portion 48, and then solidified. In this manner, the side surfaces and upper surface of the light emitting element 20 as well as a connecting portion between the light emitting element 20 and the thin metal wire 16 are covered with the sealing resin 32.

As each concave portion 18 is fed and sealed with the sealing resin 32 individually, the spreading of the fluorescent material included in the sealing resin 32 is suppressed in comparison with a case where the sealing resin 32 is formed on the entire upper surface of the substrate 40. Thus, uniformity in color of light emitted from the light emitting module is obtained.

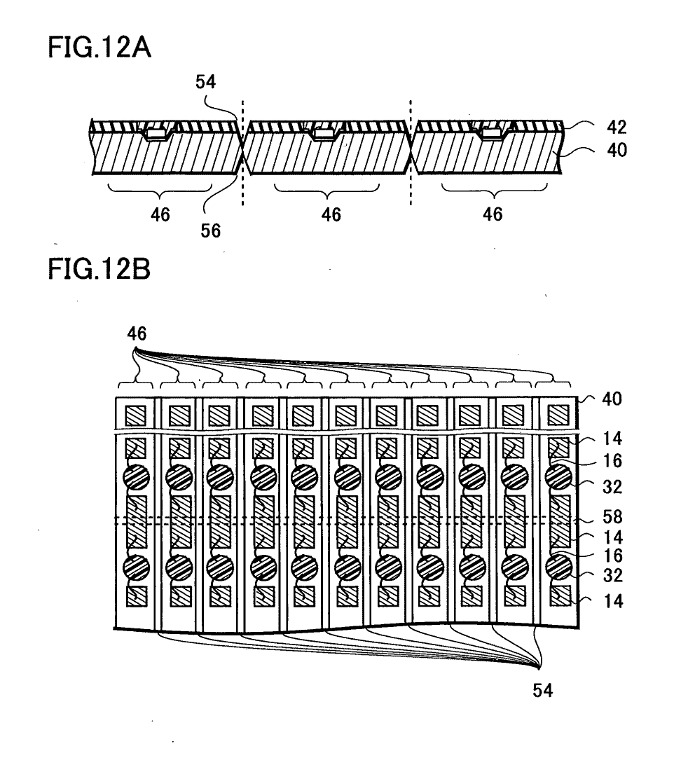

Eighth step: see FIG. 12

Next, the substrate 40 is separated to have units 46 at the positions where the first grooves 54 and the second grooves 56 are formed.

Since the two grooves 54 and 56 are formed between the two adjacent units 46, the substrate 40 is separated easily. As a way for this separation, usable are, for example, punching with a press, dicing, and bending of the substrate 40 at the positions where the two grooves are formed.

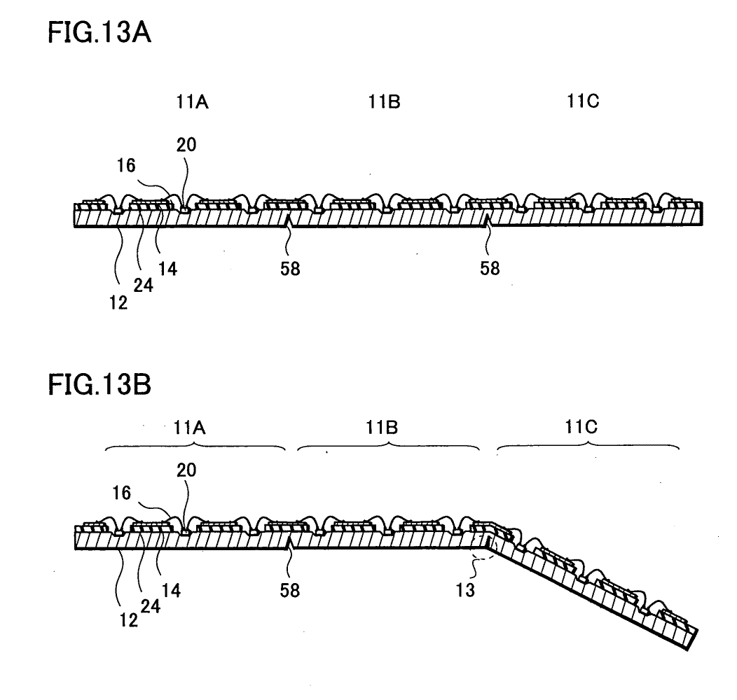

Ninth step: see FIGS. 13A and 13B

In this step, a bending process is performed on the metal substrate 12 of each unit thus separated in the preceding step. FIG. 13A is a cross-sectional view of the metal substrate 12 before the bending process. FIG. 13B is a cross-sectional view of the metal substrate 12 after the bending process.

This bending step is performed, for example, with side surfaces of the metal substrate 12 fixed as follows. Specifically, when the metal substrate 12 is bent at the boundary (portion where the groove 58 is formed) between the module segment 11B and a module segment 11C as shown in FIG. 13B, firstly, the metal substrate 12 at the module segment 11A and the module segment 11B is firstly fixed from both sides. Then, the module segment 11C is pressed from the above, and the metal substrate 12 is thus bent at the position where the groove 58 is formed. As a result, a bent portion 13 is formed as shown in FIG. 13B.

In this respect, the metal substrate 12 may be bent by using a mold. In this case, firstly, prepared is a mold whose upper portion is processed into a shape as similar to that shown in FIG. 1A. The metal substrate 12 in the form shown in FIG. 13A is placed on the upper surface of the mold. Then, pressing forces are applied to the module segment 11A and the module segment 11C from the above, and the metal substrate 12 is thus bent at the positions of the two grooves 58.

Furthermore, the metal substrate 12 is bent at the boundary (portion where another groove 58 is formed) between the module segment 11A and the module segment 11B. In this case, the module segment 11B and the module segment 11C are fixed, and then the module segment 11A is pressed from the above. Thereby, the metal substrate 12 is bent at the boundary between the module segment 11A and the module segment 11B.

The above-described bending in this step is preferably performed while the metal substrate 12, the insulating layer 24 and the conductive pattern 14 are heated. In this manner, an elastic region of the conductive pattern expands under a high temperature condition, and the bending stress caused by the bending of the metal substrate 12 is mitigated. Thus, the conductive pattern 14 and the insulating layer 24 are prevented from being damaged. Specifically, the temperature at the time of the heating is preferably 80° C. or above. The experimental results related to this point will be described later.

By performing the above-described steps, the light emitting module with the configuration shown in FIG. 1 is manufactured. Here, the order of performing these steps can be changed. For example, immediately after the step of forming grooves shown in FIG. 7, a substrate 40 may be separated into individual units 46; the bending process may be performed on each unit 46; and then light emitting elements 20 may be mounted on each unit.

### Third Embodiment

### Description of Experimental Results

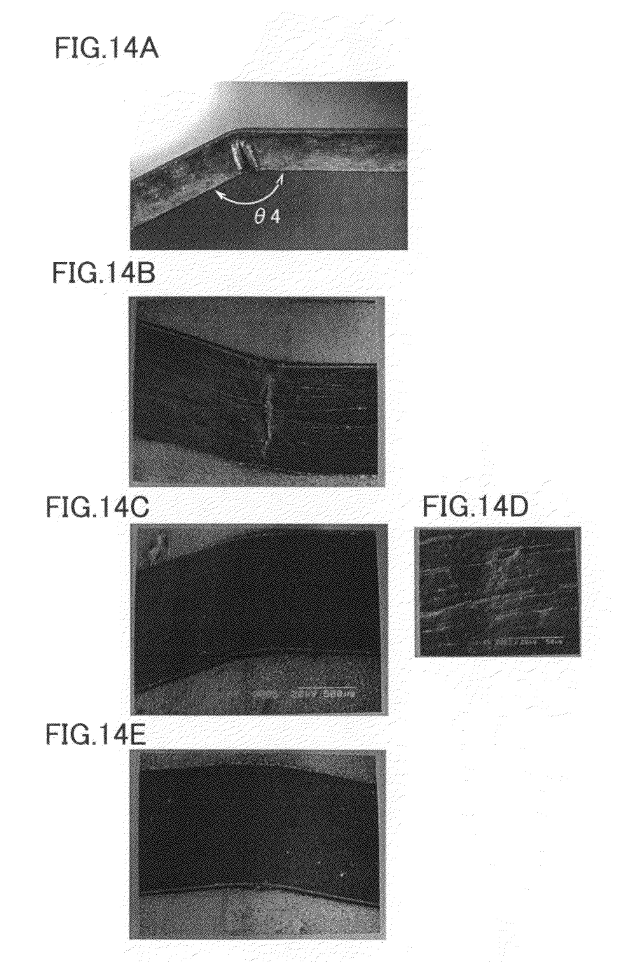

In this embodiment, with reference to FIGS. 14A to 14E, description will be given of experimental results by which the influence of metal-substrate bending on a conductive pattern is confirmed. FIG. 14A is a photograph of a bent metal substrate, taken from a side of the metal substrate. FIGS. 14B, 14C, 14D and 14E are Scanning Electron Microscope (SEM) images obtained by taking a photo of conductive patterns at bent portions after metal substrates are bent, while the metal substrates are heated at various temperatures.

As shown in FIG. 14A, a metal substrate is bent according to the method described in the second embodiment. The upper surface of the metal substrate is covered with an insulating layer made of a polyimide insulating resin. A conductive pattern is formed on the upper surface of this insulating layer. Here, an angle θ4 formed by bending the metal substrate is 148° in the actual measurement.

FIG. 14B is an SEM image obtained by taking a photo of a conductive pattern after the above-described bending is performed on a metal substrate, with the metal substrate heated to 60° C. As apparent from this drawing, a crack has occurred at the bent portion of the conductive pattern. Such a crack occurs because the bending stress is exerted on the conductive pattern when the metal substrate is bent. Given that the crack occurs on the conductive pattern at this temperature, it is predicted that, even when a metal substrate is bent as described above, at a normal temperature (for example, 30° C.), a crack would occur on a conductive pattern as in this case.

FIG. 14C is an SEM image showing a conductive pattern after a metal substrate is bent at a heating temperature of 70° C. FIG. 14D is a partially enlarged view of FIG. 14C. With reference to FIG. 14C, it is seen as if no crack has occurred on the conductive pattern. However, with reference to FIG. 14D that is the enlarged view of FIG. 14C, it is observed that a fine crack has occurred on the conductive pattern in a vertical direction.

FIG. 14E is an SEM image showing a conductive pattern when a metal substrate is bent after the heating temperature is increased to 80° C. As shown in this drawing, no crack has occurred on the conductive pattern at all. No crack occurs at a heating temperature of 80° C. because an elastic region of the conductive pattern heated to high temperature expands due to heating the metal substrate so that the conductive pattern has been in a high temperature condition. In addition, when the heating temperature is 80° C. or above, the elastic region further expands. Accordingly, it is predicted that the above-described problem of a crack occurring on the conductive pattern would not arise at 80° C. or above.

The above experiments have revealed that, bending a metal substrate after heating reduces the degree of damage to a conductive pattern. Particularly, it has been revealed that heating the metal substrate at 80° C. or above significantly reduces the degree of damage to an insulating layer and a conductive pattern caused by the bending of the metal substrate.

In a light emitting module of the present invention, a groove is formed in the back surface of a metal substrate where the light emitting element is mounted. The metal substrate is bent at the position where the groove is formed. This allows the metal substrate to be bent easily at a predetermined angle. Thereby, it is possible to have a structure of the light emitting module provided with the metal substrate bent at a predetermined angle, according to the shape of a set-up into which the light emitting module is to be incorporated.

Furthermore, since the metal substrate is bent at the position where the groove is formed in the back surface, bending stress caused by bending the metal substrate is reduced. This prevents damage, due to this bending stress, to an insulating layer and a conductive pattern formed on the upper surface of the metal substrate.

Still furthermore, an opening portion is formed by partially removing the insulating layer that covers the metal substrate, and the light emitting element is fixedly attached to the upper surface of the metal substrate, which is exposed from the bottom surface of the opening portion. Accordingly, heat generated from the light emitting element is immediately conducted to the metal substrate, and then dissipated to the outside. Thus, the rising of the temperature of the light emitting element is suppressed. Moreover, since the light emitting element is not fixedly attached to the upper surface of the insulating layer, it is no longer necessary to mix a large amount of fillers into the insulating layer in order to reduce the thermal resistance. Thus, the insulating layer can be formed mainly of a resin material, and the insulating layer having such a composition is superior in flexibility. Thereby, the insulating layer and the conductive pattern are prevented from being damaged due to the bending stress.

In a method for manufacturing the light emitting module, a metal substrate is bent at a position where a groove is formed. Accordingly, the angle at which the metal substrate is bent is easily adjusted by changing the shape of the groove.

Furthermore, when multiple units (light emitting modules) are formed from a single substrate, separation grooves for separation formed among the units and a groove formed for bending the metal substrate can be processed in one step. This reduces an increase in the number of steps for performing the bending process on the metal substrate.

Furthermore, when the bending process is performed after the metal substrate is heated, the metal substrate covered with the softened insulating layer is bent in the bending process. Accordingly, the bending stress due to the bending process is mitigated by the insulating layer. Thus, a conductive pattern and the insulating layer formed on the portion where the metal substrate is bent are prevented from being damaged due to the bending process performed on the metal substrate.

What is claimed is:

1. A light emitting module comprising:
a metal substrate whose first main surface is covered with an insulating layer;
a conductive pattern formed on a main surface of the insulating layer; and
a light emitting element electrically connected to the conductive pattern, wherein
a groove is formed in the metal substrate in a second main surface of the metal substrate, and
at a position where the groove is formed, the metal substrate is bent to a side opposite to a side where the light emitting element is mounted.

2. The light emitting module according to claim 1, wherein
at a bent portion where the metal substrate is bent, the groove is formed to have a V-shaped cross section.

3. The light emitting module according to claim 1, wherein
the metal substrate includes:
a first side and a second side being opposed to each other in a longitudinal direction of the metal substrate; and
a third side and a fourth side being opposed to each other in a latitudinal direction of the metal substrate, and
the groove is formed continuously from the first side to the second side.

4. The light emitting module according to claim 1, wherein
the light emitting element is provided in plurality in a longitudinal direction of the metal substrate, and
the light emitting elements are electrically connected to each other with the conductive pattern formed over the position where the metal substrate is bent.

5. The light emitting module according to claim 1 wherein
an opening portion is formed by removing the insulating layer, and
the light emitting element is fixedly attached to the first main surface of the metal substrate, which is exposed from a bottom portion of the opening portion.

6. The light emitting module according to claim 5 wherein
a concave portion is formed by denting the metal substrate which is exposed from the opening portion, and
the light emitting element is accommodated in the concave portion.

7. The light emitting module according to claim 6 wherein
the concave portion includes:
a bottom surface; and
a side surface that continuously connects the bottom surface and the first main surface of the metal substrate, and
the side surface is an inclined surface such that the width of the concave portion is gradually increased toward the first main surface of the metal substrate.

8. A method for manufacturing a light emitting module comprising the steps of:
forming a conductive pattern on a main surface of an insulating layer covering a first main surface of a metal substrate;
forming a groove in a second main surface of the metal substrate;
fixedly attaching a light emitting element on the first main surface of the metal substrate, and electrically connecting the light emitting element to the conductive pattern; and
at a position where the groove is formed, bending the metal substrate to a side opposite to a side where the light emitting element is mounted.

9. A method for manufacturing a light emitting module comprising the steps of:
forming a conductive pattern constituting a plurality of units, on a surface of an insulating layer covering a first main surface of a substrate;
forming separation grooves respectively in the first main surface and the second main surface of the substrate at a position corresponding to a boundary between the units, and forming a bending groove in the substrate corresponding to a position where the units are bent;
fixedly attaching a light emitting element on the substrate for each of the units, and electrically connecting the light emitting element to the conductive pattern;
at the positions where the separation grooves are formed, separating the substrate into each unit; and
at the position where the bending groove is formed, bending the substrate of the unit to a side opposite to a side where the light emitting element is mounted.

10. The method for manufacturing a light emitting module according to any one of claims 8 and 9, wherein in the step of bending the substrate, the heated substrate is bent.
